(19) United States
(12) Patent Application Publication
(10) Pub. No.: US 2024/0413111 A1
(43) Pub. Date: Dec. 12, 2024

(54) INLINE RESISTOR INTEGRATED WITH CONDUCTIVE CONTACT PAD STRUCTURE

(71) Applicant: BAE SYSTEMS Information and Electronic Systems Integration Inc., Nashua, NH (US)

(72) Inventors: Nathaniel P. Wyckoff, Marion, IA (US); Alexander S. Warren, North Liberty, IA (US); Jacob R. Mauermann, Marion, IA (US); Justin D. Smith, North Liberty, IA (US)

(73) Assignee: BAE SYSTEMS Information and Electronic Systems Integration Inc., Nashua, NH (US)

(21) Appl. No.: 18/206,731

(22) Filed: Jun. 7, 2023

(51) Int. Cl. H01L 23/00

(52) U.S. Cl. CPC H01L 24/13; H01L 2224/16225; H01L 2924/14; H01L 2924/15311

(57) ABSTRACT

An integrated circuit structure includes (i) a first layer including a first metal, (ii) a second layer above and in contact with the first layer, the second layer including a resistive material, and (iii) a third layer above and in contact with the second layer, the third layer including a second metal. In an example, the resistive material is different from one or both the first metal and the second metal. An interconnect component is above and in contact with the second layer. In an example, the interconnect component is a solder bump or a solder ball. In an example, a resistivity of the resistive material of the second layer is at least 20%, or at least 50% greater than a resistivity of each of the first and third layers. In an example, the resistive material includes a third metal different from the first and second metals and/or a metalloid.

### TECHNICAL FIELD

The present disclosure relates generally to integrated circuits, and more particularly to inline resistor structures for integrated circuits.

### BACKGROUND

There exists a variety of chip packaging techniques, such as ball grid array (BGA) and flip-chip, for mounting an integrated circuit die and package assembly on a circuit board (such as a printed circuit board or PCB). For example, in a flip-chip configuration, the die is coupled to a carrier substrate (or package) through a plurality of solder bumps. The resultant integrated circuit package may be coupled to a circuit board using solder balls, for example, in a BGA configuration. For instance, the die may include a plurality of contact pads, where each contact pad of the die is coupled to a corresponding solder bump. Similarly, the carrier substrate may include a plurality of contact pads, where each contact pad of the carrier substrate is coupled to a corresponding solder bump or a corresponding solder ball. Furthermore, the circuit board may include a plurality of contact pads, where each contact pad of the circuit board is coupled to a corresponding solder ball. A surface mount component such as a resistor can be mounted on the PCB and electrically coupled to one or more of the contact pads.

### BRIEF DESCRIPTION OF THE DRAWINGS

FIG. 1 illustrates a cross-sectional view of an integrated circuit structure comprising a device and a resistive contact pad structure on the device, wherein the resistive contact pad structure comprises a layer having relatively high resistivity (e.g., compared to a resistivity of one or more other layers of the resistive contact pad structure), wherein the resistive contact pad structure is configured to receive an interconnect component, such as a conductive ball or a conductive bump, and wherein the interconnect component is to couple the device to another device, according to an embodiment of the present disclosure.

FIG. 2 illustrates a cross-sectional view of an integrated circuit structure comprising the resistive contact pad structure of FIG. 1, as well as a non-resistive contact pad structure laterally adjacent to the resistive contact pad structure, according to an embodiment of the present disclosure.

FIG. 3 illustrates a cross-sectional view of the integrated circuit structure of FIG. 2, with two interconnect components respectively on the resistive contact pad structure and the non-resistive contact pad structure, according to an embodiment of the present disclosure.

FIG. 4 illustrates a cross-sectional view of an integrated circuit structure comprising two laterally adjacent resistive contact pad structures, wherein the two resistive contact pad structures are conjoined by a continuous and monolithic resistor layer that is common to both the resistive contact pad structures, according to an embodiment of the present disclosure.

FIG. 5 illustrates a cross-sectional view of an integrated circuit structure comprising two laterally adjacent resistive contact pad structures, and another laterally adjacent non-resistive contact pad structure, according to an embodiment of the present disclosure.

FIG. 6 illustrates a cross-sectional view of an integrated circuit structure comprising a device and a resistive contact pad structure on the device, wherein the resistive contact pad structure comprises a layer having relatively high resistivity (e.g., compared to a resistivity of one or more other layers of the resistive contact pad structure) and in contact with an underlying conductive line, according to an embodiment of the present disclosure.

FIG. 7A illustrates a cross-sectional view of an integrated circuit system employing any one or more of the resistive contact pad structures described with respect to FIGS. 1-6, according to an embodiment of the present disclosure.

FIG. 7B illustrates a cross-sectional view of another integrated circuit system 750 employing one or more of the resistive contact pad structures described above with respect to FIGS. 1-6, according to an embodiment of the present disclosure.

FIG. 8 illustrate a flowchart depicting a method of forming the example integrated circuit structures of FIGS. 1-6, in accordance with an embodiment of the present disclosure.

FIGS. 9A, 9B, 9C, 9D, 9E, 9F, 9G, 9H, and 9I collectively illustrate an example integrated circuit structure in various stages of processing in accordance with the methodology of FIG. 8, in accordance with an embodiment of the present disclosure.

The figures depict various embodiments of the present disclosure for purposes of illustration only and are not necessarily drawn to scale. Numerous variations, configurations, and other embodiments will be apparent from the following detailed discussion.

### DETAILED DESCRIPTION

Disclosed herein are resistive contact pad structures that include inline resistors. For example, instead of forming a separate resistor coupled to a contact pad, the contact pad itself is formed to have a relatively high resistance layer. Such a resistive contact pad structure may be formed at a die level, at a package level, or at a circuit board level. For example, the resistive contact pad structure may be coupled to a conductive bump or a ball, such as a conductive solder bump or a conductive solder ball. The resistive layer of the resistive contact pad structure may be coupled, for instance, between two conductive contact pads, or between a conductive contact pad and another conductive element (e.g., conductive line). Such a configuration may be used to help reduce the need for surface mount resistors.

In one embodiment, such a resistive contact pad structure includes a lower layer, an upper layer above the lower layer, and a resistor layer between the lower layer and the upper layer. The lower layer may be elementally and/or dimensionally similar to any other laterally adjacent non-resistive contact pad structure. The resistor layer and the upper layer are added to the lower layer, to form the resistive contact pad structure. In an example, a height and/or a material of the resistor layer may be selected, such that the resistor layer has relatively high resistance. For example, the resistance of the resistive contact pad structure may be relatively higher than a laterally adjacent non-resistive contact pad structure that has only a lower layer (but not the resistor layer and the upper layer). In the resistive contact pad structure, the upper layer may receive, for example, a corresponding solder ball or a solder bump.

In an example, the resistor layer comprises a resistive material, such as a metal or metalloid, such as germanium or tellurium, e.g., having relatively higher resistivity (e.g., higher than copper or nickel, for example). In another example, the resistive material of the resistor layer comprises a metal oxide and/or a metal nitride, such as tantalum oxide, titanium oxide, aluminum oxide, aluminum nitride, and/or other nitride or oxide having a desired resistivity greater than a given conductive pad (or pads). In yet another example, a carbide, an oxynitride, an oxycarbide, or an oxycarbonitride of one or more metals may also be used instead. A choice of material, whether elemental, or a compound, or an alloy, or a metalloid, a metal oxide, or other resistive conductor, for the resistor layer may depend on a desired resistance of the resistive contact pad structure. Numerous variations and embodiments will be apparent in light of the present disclosure.

### General Overview

There remain several non-trivial issues with respect to designing and forming contact pads for integrated circuit structures. For example, a design of an integrated circuit may necessitate a contact pad to be coupled in series to a surface mount resistor. However, adding a surface mount resistor in series with the contact pad results in increased area of the circuit structure and/or may increase the cost.

Accordingly, techniques are described herein to form resistive contact pad structures that include inline or integrated resistors, e.g., thereby providing a resistance within the resistive contact pad structures, and thus reducing the need for external resistance such as a surface mount resistor. For example, instead of forming a separate surface mount resistor coupled in series to the contact pad, the resistive contact pad structure itself is formed to have a relatively high resistance comparable to that of a surface mount resistor.

In one embodiment, the resistive contact pad structures described herein can be coupled at any level of an integrated circuit system. For example, the resistive contact pad structures can be on an integrated circuit die, e.g., to couple the die in a flip-chip configuration to a package carrier substrate through corresponding solder bumps. Similarly, the resistive contact pad structures can be on the package carrier substrate, e.g., to couple the package carrier substrate through corresponding solder bumps to the die, or a PCB. In another example, the resistive contact pad structures can be on the package carrier substrate, e.g., to couple the package carrier substrate through corresponding solder balls to a circuit board such as a PCB. In yet another example, the resistive contact pad structures can be on the circuit board, e.g., to couple the circuit board through corresponding solder balls to the package carrier substrate. Thus, in an example, a resistive contact pad structure can be coupled to an interconnect component, such as a solder ball or a solder bump, and the resistive contact pad structure may be at a die level, at a package level, or a board level.

In an example, a device (such as a die, a package carrier substrate, or a circuit board) includes a plurality of contact pad structures, where only some such contact pad structures are resistive contact pad structures, e.g., based on a design of the device. The remaining contact pads may be non-resistive contact pad structures, having a negligible resistance (highly conductive) or a resistance otherwise substantially lower than an intentionally higher resistance of the resistive contact pad structures.

In one embodiment, a resistive contact pad structure includes a lower layer, an upper layer above the lower layer, and a resistor layer between the lower layer and the upper layer. The lower layer may be elementally, compositionally, and/or dimensionally similar to any other laterally adjacent non-resistive contact pad structure. For example, the non-resistive contact pad structures include only the lower layer (without any resistor layer and upper layer there-above). Note that although there is no upper layer within the non-resistive contact pad structures, this layer is nonetheless identified as the lower layer of the non-resistive contact pad structures, for case of identification.

For example, the lower layer of the resistive contact pad structures and the non-resistive contact pad structures may be formed using a same process flow, and may be elementally, compositionally, and/or dimensionally similar, and may have coplanar upper and lower surfaces. In an example, the lower layer of the resistive contact pad structures and the non-resistive contact pad structures comprises nickel, copper, aluminum, gold, silver, platinum, and/or other metals/alloys suitable for conductive contact pads.

In one embodiment, a height and/or a material of the resistor layer may be selected, such that the resistor layer has high resistance, e.g., to resultantly increase a resistance of the resistive contact pad structure. For example, the resistance of the resistive contact pad structure may be relatively higher than a laterally adjacent non-resistive contact pad structure that has only the lower layer (but not the resistor layer and the upper layer). For example, the resistor layer comprises a metal or metalloid, such as germanium or tellurium, e.g., having relatively high resistivity (e.g., higher than copper or nickel or other highly conductive pure metals or alloys, for example). In another example, the resistor layer comprises a metal oxide and/or a metal nitride, such as tantalum oxide, titanium oxide, aluminum oxide, aluminum nitride, and/or other appropriate nitride or oxide. In yet another example, carbide, oxynitride, oxycarbide, or oxycarbonitride of one or more metals may also be used instead. A choice of material for the resistor layer may depend on a desired resistance of the resistive contact pad structure, in an example.

In the resistive contact pad structure, the upper layer receives a corresponding solder ball or a solder bump. In an example, the upper layer of the resistive contact pad structures comprises nickel, copper, aluminum, gold, silver, platinum, and/or other appropriate metals/alloys generally used for contact pad structures. The upper and lower layers of the resistive contact pad structures may be elementally the same.

In an example, the resistive contact pad structures and the non-resistive contact pad structures may be laterally adjacent (e.g., see FIGS. 2, 3, 6). In some examples, a first the resistive contact pad structure may also be laterally adjacent to a second resistive contact pad structure. In some such examples where the first and second resistive contact pad structures are laterally adjacent, there may be a common, continuous, and monolithic resistor layer for both the first and second resistive contact pad structures. In an example, the first and second resistive contact pad structures may be spaced apart by tens, hundreds, or thousands of microns. Accordingly, although the common resistor layer electrically couples the first and second resistive contact pad structures, a resistance of the section of the resistor layer between the two resistive contact pad structures may be relatively high (e.g., in the range of tens or hundreds of ohms, kilo-ohms, mega-ohms or giga-ohms).

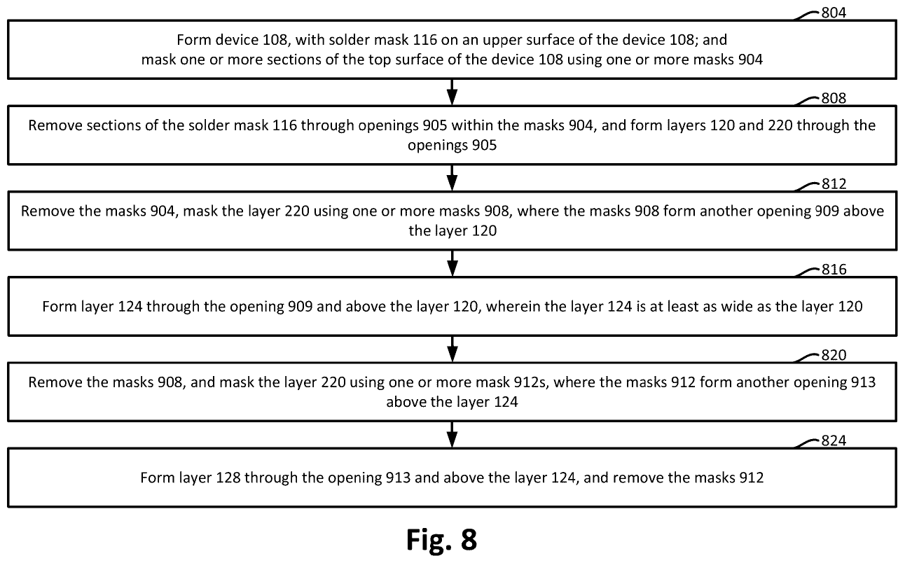

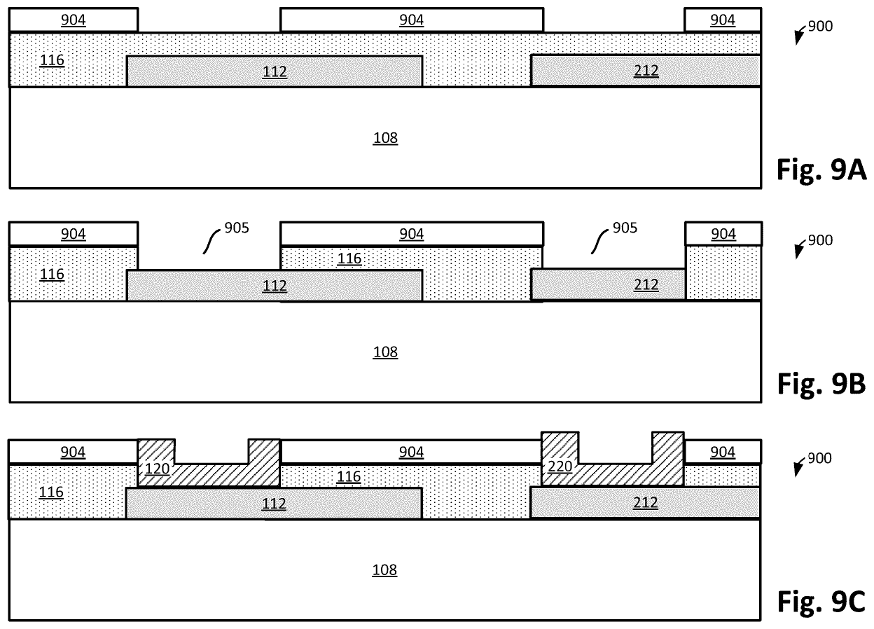

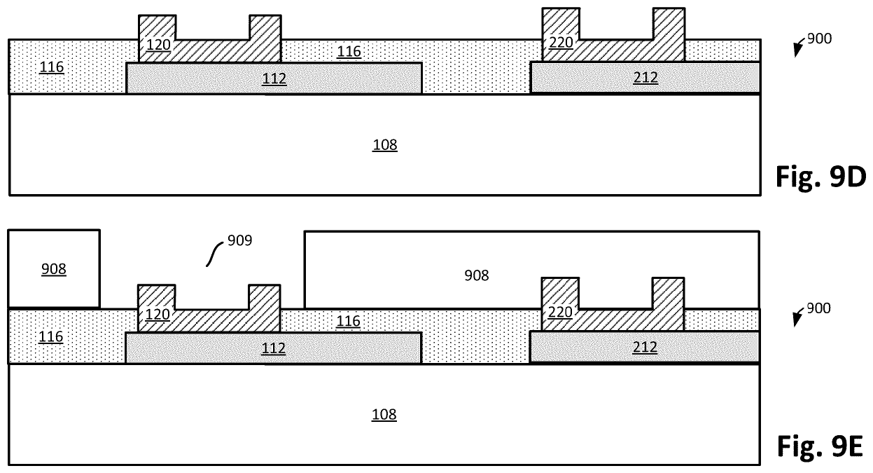

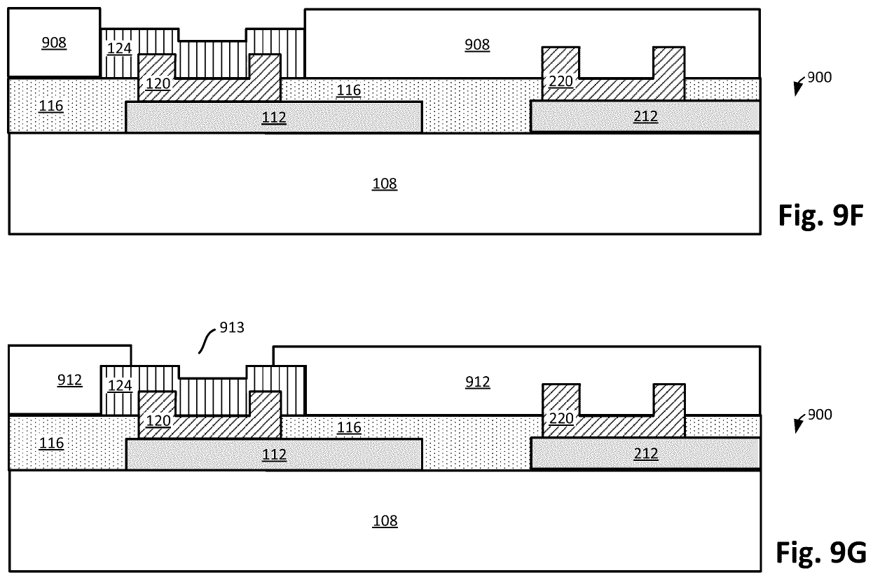

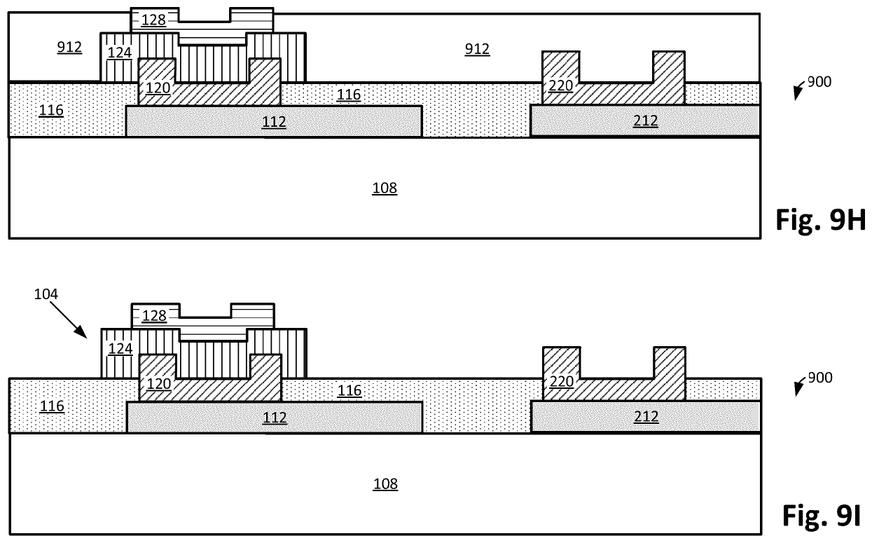

In one embodiment, when forming the resistive contact pad structures, the resistor layer is deposited above the lower layer of the resistive contact pad structures, while the lower layer of the non-resistive contact pad structures are masked off. In some examples, the resistor layer comprises a metal oxide, and in some such examples, the resistor layer is deposited conformally using a reactive deposition process. For example, during the reactive deposition process, the metal is deposited on the lower layer of the resistive contact pad structures, and the deposition process is carried out in an oxygen-rich environment. Based on the process parameters maintained in the deposition chamber, the deposited metal may be oxidized (or the oxidized metal may be deposited), thereby forming the metal oxide resistor layer. In an example, a rate of oxidation may be controlled, to control a resistance of the resistor layer. An example formation process of the resistive contact pad structures is described below with respect to FIGS. 8 and 9A-9I.

As used herein, the term “about” indicates that the value listed may be somewhat altered or otherwise within an acceptable tolerance, as long as the alteration does not result in nonconformance of the process or device. For example, for some elements the term “about” can refer to a variation of ±0.1%, for other elements, the term “about” can refer to a variation of ±1% or ±10%, or any point therein. As also used herein, terms defined in the singular are intended to include those terms defined in the plural and vice versa.

Reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc.

As used herein, the term “substantially”, or “substantial”, is equally applicable when used in a negative connotation to refer to the complete or near complete lack of an action, characteristic, property, state, structure, item, or result. For example, a surface that is “substantially” flat would either completely flat, or so nearly flat that the effect would be the same as if it were completely flat.

Materials that are “compositionally different” or “compositionally distinct” as used herein refers to two materials that have different chemical compositions. For example, an alloy of gold and copper may be compositionally different from an alloy of gold, copper, and silver. Similarly, an alloy of gold and copper with 20% copper may be compositionally different from an alloy of gold and copper with 30% copper. If two materials are “elementally different,” then one of the materials has an element that is not in the other material. Thus, an alloy of gold and copper with 20% copper may be elementally same as an alloy of gold and copper with 30% copper.

### Resistive Contact Pad Structure

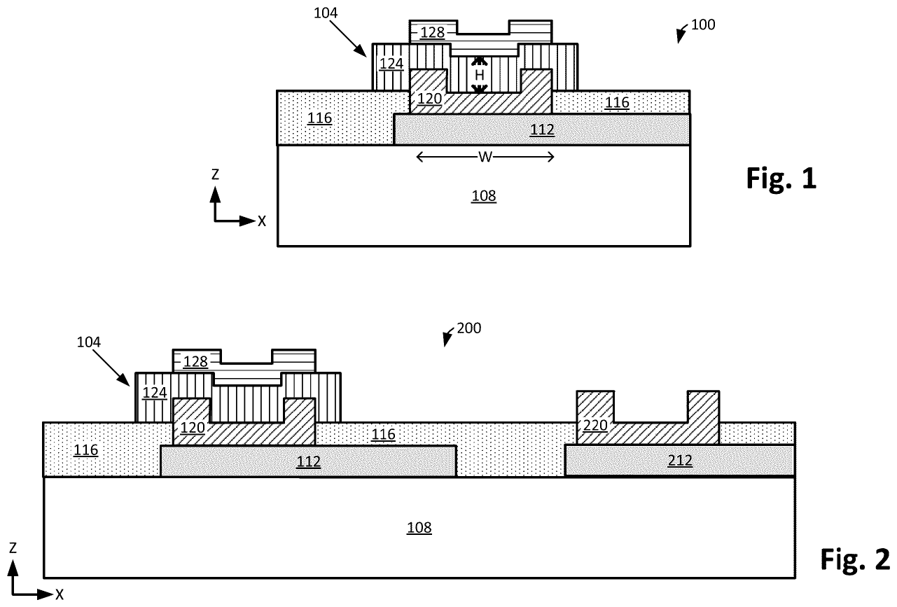

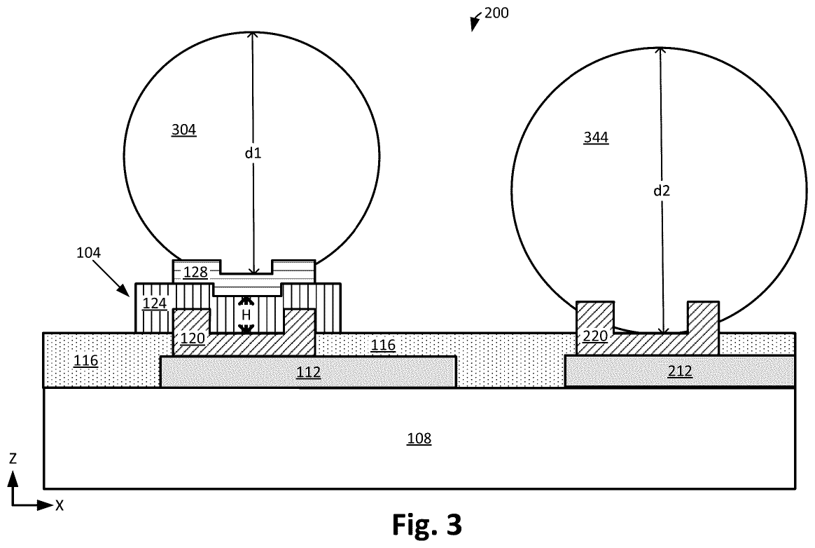

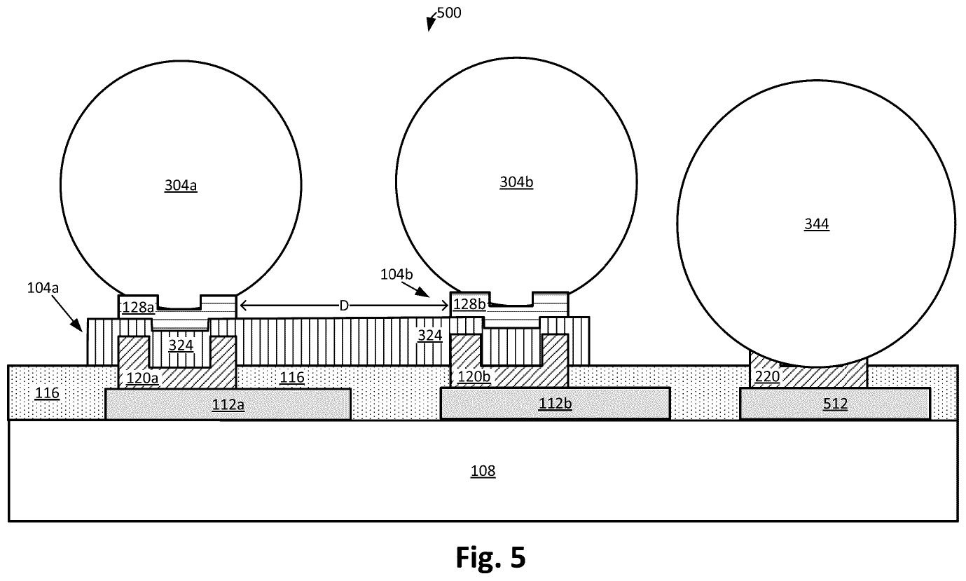

FIG. 1 illustrates a cross-sectional view of an integrated circuit structure 100 comprising a device 108 and a resistive contact pad structure 104 on the device 108, wherein the resistive contact pad structure 104 comprises a layer 124 having relatively high resistivity (e.g., compared to a resistivity of one or more other layers of the resistive contact pad structure 104), and wherein the resistive contact pad structure 104 is configured to receive an interconnect component, such as a conductive ball or a conductive bump (see FIG. 3 or 5, not illustrated in FIG. 1), and wherein the interconnect component is to couple the device 108 to another device, according to an embodiment of the present disclosure.

In one embodiment, the device 108 may be an appropriate device, such as an integrated circuit die or chip, a carrier substrate, a printed circuit board, or another appropriate device to which an interconnect component, such as a solder ball or a solder bump, may be coupled. Examples of the device 108 will be described below.

In one embodiment, the device 108 comprises a conductive line or trace 112 that extends below the resistive contact pad structure 104. The line 112 is coupled to, e.g., in physical and electrical contact with, the resistive contact pad structure 104. In some examples, the line 112 comprises one or more metals and/or alloys thereof. In some such examples, the line 112 comprises copper, aluminum, nickel, gold, silver, platinum, and/or another conductive metal used to form lines or traces within dies, carrier substrates, and/or printed circuit boards. The line 112 electrically couples the resistive contact pad structure 104 to one or more other components of the device 108.

In one example, the resistive contact pad structure 104 can be considered to be external to the device 104 and on the device 104. In another example, the resistive contact pad structure 104 can be considered to be a part of the device 104.

In one embodiment, the resistive contact pad structure 104 comprises a lower layer 120, an intermediate layer 124, and an upper layer 128, which are also referred to herein as a first layer 120, a second layer 124, and a third layer 128, respectively. As illustrated, the layer 124 is between the layers 120 and 128. For example, the layer 124 physically and electrically separates the layers 120 and 128, such that the layers 120 and 128 can be electrically coupled to each other through the layer 124 (e.g., the layers 120 and 128 cannot be directly in contact with each other).

For example, to prevent or reduce chances of direct physical contact between the layers 120 and 128, the layer 124 is at least as large or wide as one or both of the layers 120, 128, e.g., in the X-Y axis directions. Thus, for the orientation of FIG. 1, a horizontal span of the layer 124 is at least as large as horizontal spans of one or both the layers 120 and 128. In the example of FIG. 1, in the horizontal plane, the layer 124 is larger than each of the layers 120 and 128.

In one embodiment, at least a section of an upper surface of the device 108 is covered by a mask 116, where the mask 116 is a solder mask, in an example. The solder mask 116 has an opening, and the layer 120 extends within the opening in the solder mask 116, and contacts the conductive line 112, as illustrated.

In one embodiment, the layer 120 comprises conductive material, such as one or more metals and/or alloys thereof. In an example and although not illustrated in FIG. 1, the layer 120 comprises a barrier or liner layer, and fill material within the barrier or liner layer; while in another example, such a barrier or liner layer may be absent.

As described below, the layer 120 (or other layers that are similar to the layer 120) is configured as a pad to receive a solder ball or a solder bump; although due to the structure of the resistive contact pad structure 104, the layer 120 doesn't receive any such solder ball or a solder bump. Accordingly, in an example, the layer 120 comprises appropriate metals and/or alloys thereof, which can adhere to a solder ball or a solder bump. For example, the layer 120 comprises nickel, copper, aluminum, gold, silver, platinum, and/or other appropriate metals/alloys generally used for contact pad structures.

In one embodiment, the layer 128 similarly comprises a conductive material, such as one or more metals and/or alloys thereof. In an example and although not illustrated in FIG. 1, the layer 128 comprises a barrier or liner layer, and fill material within the barrier or liner layer; while in another example, such a barrier or liner layer may be absent. The layer 128 is configured as a contact pad structure to receive a solder ball or a solder bump (e.g., see FIG. 3). Accordingly, in an example, the layer 128 comprises appropriate metals and/or alloys thereof, which can adhere to a solder ball or a solder bump. For example, the layer 128 comprises nickel, copper, aluminum, gold, silver, platinum, and/or other appropriate metals/alloys used for contact pad structures.

Thus, the layers 120 and 128 are contact pad structures, with the layer 124 between the two contact pad structures 120, 128, and the combination of the contact pad structures 120, 128 and the layer 124 forms the resistive contact pad structure 104. In one embodiment, the layer 124 acts as a resistor (such as an inline resistor) between the two layers 120 and 128. For example, the layer 124 has substantially higher resistivity than the layers 120 and 128. As illustrated, the layers 120, 124, and 128 are in series, with the layer 124 between the layers 120 and 128. Introducing the layer 124 between the layers 120 and 128 increases an overall resistance of the resistive contact pad structure 104. Accordingly, the contact pad structure 104 is also referred to herein as a “resistive” contact pad structure.

Thus, in an application where a resistor is designed to be in series with a contact pad, instead of forming a separate resistor, the layer 124 is added to the contact pad structure. This results in an overall increase in the resistance of the resistive contact pad structure 104, which is equivalent to having a resistor is series with the contact pad structure.

In one embodiment, a resistance of the resistor layer 124 may be tuned, e.g., by selecting an appropriate material for the layer 124 and/or by tuning a height H of the layer 124 (see FIG. 1). For example, a shorter height H would result in a lower resistance between the layers 120 and 128. In contrast, a taller height H would result in a higher resistance between the layers 120 and 128, e.g., due to the relatively higher resistivity of the layer 124. In an example, the height H may range between 0.1 microns to 25 microns, or in the subrange of 0.1 to 20 microns, or 0.1 to 10 microns, or 0.1 to 5 microns, or 0.5 to 25 microns, or 0.5 to 10 microns, or 0.5 to 5 microns, or 1 to 25 microns, or 1 to 15 microns, or 1 to 10 microns, or 1 to 5 microns, or 2 to 25 microns, or 2 to 10 microns, or 2 to 5 microns, in an example. As described, the height H may be controller to achieve a desired resistance of the resistive contact pad structure 104.

In one embodiment, the layer 124 comprises resistive material, e.g., having resistivity higher than conductive material such as copper, nickel, aluminum, and/or other metals used for conductive lines and non-resistive contact pads. In an example, depending on material selection for the layers 120, 124, 128, a resistivity of the resistive material of the layer 124 may be more than a resistivity of one or both the layers 120 and 128 by at least 10%, or at least 20%, or at least 40%, or at least 50%, or at least 100%, or at least 200%, or at least 400%, or at least 500%, or at least 1000%, for example. In an example, a resistivity of the resistive material of the layer 124 is at least 0.000001 ohm-meters, or at least 0.000016 ohm-meters (e.g., which is a resistivity of graphite form of carbon), or at least 0.005 ohm-meters (e.g., which is a resistivity of tellurium), or at least 0.05 ohm-meters, or at least 0.1 ohm-meters, or at least 0.5 ohm-meters, or at least 1 ohm-meter, or at least 5 ohm-meters, or at least 10 ohm-meters, or at least 25 ohm-meters, or at least 100 ohm-meters.

In an example, the resistive material of the layer 124 comprises one or more metals, one or more metalloids, and/or oxides and/or nitrides thereof. For example, the layer 124 comprises relatively high resistance metals or metalloids, such as germanium or tellurium (e.g., compared to resistivity of copper or nickel, for example). In another example, the layer 124 comprises a metal oxide and/or a metal nitride, such as tantalum oxide, titanium oxide, aluminum oxide, aluminum nitride, and/or other appropriate nitride or oxide. In yet another example, carbide, oxynitride, oxycarbide, or oxycarbonitride of one or more metals may also be used instead. A choice of material for the layer 124 may depend on a desired resistance of the resistive contact pad structure 104, in an example.

In one embodiment, when the layer 124 comprises a metal and/or a metal oxide, a rate of oxidation may be controlled, e.g., to control a resistance of the layer 124. The metal oxide may have a higher resistance than the metal. In an example, the entire metal of the layer 124 may be oxidized, e.g., to achieve a relatively higher resistance. In another example, only a section (and not an entirety) of the metal of the layer 124 may be oxidized, e.g., to achieve a relatively lower resistance. For example, a surface area of the metal of the layer 124 may be oxidized, to achieve a relatively lower resistance. Thus, an amount of the metal of the layer 124 that is oxidized may be controlled, to tune a resistance of the layer 124, in an example.

Thus, as described above, depending on a thickness or height H of the layer 124 and/or a selection of material for the layer 124, the layer 124 can have high resistance, e.g., compared to the layers 120 and/or 128. For example, the resistance of each of the layers 120 and 128 can be measured in fractions of ohms, or a few ohms (e.g., less than 100 ohms, or less than 50 ohms, or less than 20 ohms, or less than 10 ohms, or less than 5 ohms, or less than 2 ohms, or less than 1 ohm, for example). In contrast, a resistance of the layer 124 (e.g., for conduction of current between the layers 120, 128) may be tens of ohms, or hundreds of ohms, or a few kilo ohms, or a few mega ohms, for example (e.g., at least 10 ohms, or at least 20 ohms, or at least 50 ohms, or at least 100 ohms, or at least 200 ohms, or at least 500 ohms, or at least 1,000 ohms, or at least 2,000 ohms, or at least 5,000 ohms, or at least 10,000 ohms, for example).

As illustrated in FIG. 1, the layer 120 has a width W e.g., along the X axis direction of FIG. 1. For example, the mask 116 has an opening having the width W, and the layer 120 is formed at least in part within the opening. The width W may range from a few microns to hundreds of microns, e.g., depending on an application area in which the resistive contact pad structure 104 is used. For example, as will be described below, if the resistive contact pad structure 104 is on a die in a flip-chip configuration or on a surface of a carrier substrate facing a die (e.g., if the resistive contact pad structure 104 is to receive a solder bump), the width W can be within a range of 10-200 microns, such as in the subrange of 10-150 microns, or 10-100 microns, or 10-50 microns, or 50-200 microns, or 50-100 microns, for example. In another example, and as also will be described below, if the resistive contact pad structure 104 is on a printed circuit board (PCB) or on a surface of a carrier substrate facing a PCB (e.g., if the resistive contact pad structure 104 is to receive a solder ball), the width W can be within a range of 200-900 microns, such as in the subrange of 200-700 microns, or 200-400 microns, or 400-900 microns, or 400-600 microns, or 500-900 microns, for example.

FIG. 2 illustrates a cross-sectional view of an integrated circuit structure 200 comprising the resistive contact pad structure 104 of FIG. 1, as well as a non-resistive contact pad structure 220 laterally adjacent to the resistive contact pad structure 104, according to an embodiment of the present disclosure. The resistive contact pad structure 104 of FIG. 2 is similar to the resistive contact pad structure 104 of FIG. 1, and the various layers of the two resistive contact pad structures 104 in the two figures are labelled similarly.

The structure 200 of FIG. 2 further includes a regular or non-resistive contact pad structure 220. The contact pad structure 220 is referred to herein as a “regular contact pad structure” or a “non-resistive contact pad structure,” because, unlike the resistive contact pad structure 104 (e.g., which included the resistor layer 124), the contact pad structure 220 doesn't include such a resistor layer. Thus, the contact pad structure 220 has a resistance that is substantially less than a resistance of the resistive contact pad structure 104, and hence, the contact pad structure 220 is also referred to as a regular or non-resistive contact pad structure.

In an example, the non-resistive contact pad structure 220 is similar to the layer 120 of the resistive contact pad structure 104. For example, the layer 120 may be configured as a non-resistive contact pad structure, and adding the layers 124 and 128 to the layer 120 results in the resistive contact pad structure 104. For example, the layers 120 and 220 may be formed using a common process flow, resulting in compositionally or elementally similar and/or dimensionally similar layers 120 and 220. Subsequently, the layers 124 and 128 are formed on the layer 120, resulting in the resistive contact pad structure 104. In an example, an upper surface and/or a lower surface of the layer 120 is substantially coplanar with an upper surface and/or a lower surface of the layer 220, respectively.

FIG. 3 illustrates a cross-sectional view of the integrated circuit structure 200 of FIG. 2, with two interconnect components 304 and 344 respectively on the resistive contact pad structure 104 and the non-resistive contact pad structure 220, according to an embodiment of the present disclosure. In one embodiment, the interconnect components 304 and 344 are solder bumps or solder balls, e.g., depending on an application in which the contact pad structures 104 and 220 are deployed. For example, as will be described below, if the contact pad structures 104, 220 are on a die in a flip-chip configuration or on a surface of a carrier substrate facing a die, the interconnect components 304 and 344 may be conductive bumps, such as solder bumps. In another example, and as also will be described below, if the contact pad structures 104, 220 are on a PCB or on a surface of a carrier substrate facing a PCB, the interconnect components 304 and 344 may be conductive balls, such as solder balls.

In an example, a diameter along a vertical Z-axis of the interconnect component 304 is d1, and a diameter along the vertical Z-axis of the interconnect component 344 is d2. Because of the height H of the layer 124 and a height of the layer 128, the diameter d1 is more than the diameter d2. The diameters d1 and d2 are in the range of tens or hundreds of microns, such as at least 20 microns, or at least 40 microns, or at least 50 microns, or at least 70 microns, or at least 100 microns, or at least 150 microns, or at least 200 microns, or at least 400 microns, e.g., depending on the application in which the contact pad structures 104 and 220 are used for.

In an example, as the diameters d1 and d2 are substantially higher than the heights of the layers 124, 128, the difference between the diameters d1 and d2 are negligible. For example, the difference between the diameters d1 and d2 are small enough, such that dimensionally similar solder material (or another conductive material) may be used to form the interconnect components 304 and 344. For example, the interconnect components 304 and 344 may be formed using the same interconnect component formation process, without additional processing employed to account for the difference in the diameters d1 and d2.

However, in another example, because the diameter d1 may be smaller than the diameter d2, less conductive material may be used to form the interconnect component 304 than that used to form the interconnect component 344.

As illustrated, a lower surface of the interconnect component 344 is on a first horizontal plane that is lower than a second horizontal plane of a lower surface of the interconnect component 304. Thus, the lower surface of the interconnect component 344 is lower than the lower surface of the interconnect component 304, as illustrated in FIG. 3.

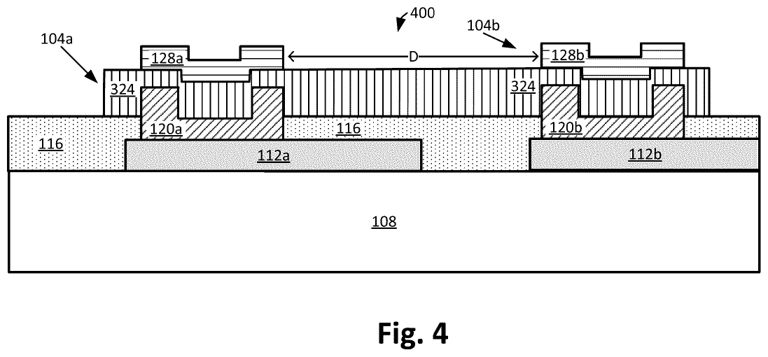

FIG. 4 illustrates a cross-sectional view of an integrated circuit structure 400 comprising two laterally adjacent resistive contact pad structures 104a and 104b, wherein the two resistive contact pad structures 104a and 104b are conjoined by a continuous and monolithic resistor layer 324 that is common to both the resistive contact pad structures 104a and 104b, according to an embodiment of the present disclosure. For example, the resistive contact pad structure 104a comprises layers 120a, 324, 128a, e.g., which are elementally and/or compositionally similar to the above described layers 120, 124, and 128, respectively, of the resistive contact pad structure 104 of FIG. 1. Similarly, the resistive contact pad structure 104b comprises layers 120b, 324, 128b, e.g., which are elementally and/or compositionally similar to the above described layers 120, 124, and 128, respectively, of the resistive contact pad structure 104 of FIG. 1.

Thus, the resistive contact pad structures 104a and 104b each has similar structure as the above described resistive contact pad structure 104 of FIG. 1. However, in FIG. 4, the resistor layer 324 is common to both the resistive contact pad structures 104a and 104b. For example, the layer 324 extends continuously and monolithically between the resistive contact pad structures 104a and 104b. Thus, a section of the layer 324 is included in the resistive contact pad structure 104a, and another section of the layer 324 is included in the resistive contact pad structure 104b.

As described above, the resistor layer 324 has relatively high resistivity, e.g., substantially higher than the resistivity of the layers 120a, 120b, 128a, 128b. As illustrated in FIG. 4, the resistive contact pad structures 104a and 104b are separated by a lateral distance D. In an example, the distance D is at least 100 microns, or at least 200 microns, or at least 400 microns, or at least 600 microns, or at least 800 microns, or at least 1000 microns, or at least 1500 microns, or at least 2000 microns, or at least 3000 microns, or at least 4000 microns, or at least 5000 microns, for example. Accordingly, a resistance of a portion of the layer 324, which is between the two resistive contact pad structures 104a and 104b, is in mega ohm or even giga ohm range. For example, a resistance of a portion of the layer 324, which is between the two resistive contact pad structures 104a and 104b, is at least 1 mega ohm, or at least 5 mega ohms, or at least 20 mega ohms, or at least 50 mega ohms, or at least 100 mega ohms, or at least 200 mega ohms, or at least 400 mega ohms, or at least 500 mega ohms, or at least 800 mega ohms, or at least 1,000 mega ohms, or at least 2,000 mega ohms. Thus, although the layer 324 physically and electrically couples the two resistive contact pad structures 104a and 104b, due to the above discussed high resistance of the section of the layer 324 between the two resistive contact pad structures 104a, 104b, for practical purposes, the two resistive contact pad structures 104a, 104b may be considered to be electrically isolated from each other.

In an example, the layer 324 may be common to both the resistive contact pad structures 104a, 104b, e.g., due to an case in formation of the layer 324. For example, during formation of the structure 400, the layer 324 may be blanket deposited on the layers 120a and 120b. Because both the resistive contact pad structures 104a, 104b use the resistor layer 324 and due to the high resistivity of the layer 324 described above, the section of the layer 324 between the two resistive contact pad structures 104a, 104b may not be later removed, thereby forming the structure 400 of FIG. 4.

FIG. 5 illustrates a cross-sectional view of an integrated circuit structure 500 comprising two laterally adjacent resistive contact pad structures 104a and 104b (e.g., see FIG. 4), and another laterally adjacent non-resistive contact pad structure 220 (e.g., see FIGS. 2 and 3), according to an embodiment of the present disclosure. For example, the resistive contact pad structures 104a, 104b and the non-resistive contact pad structure 220 are respectively coupled to interconnect components 304a, 304b, 344. The structure 500 of FIG. 5 will be apparent, based on the above description with respect to FIGS. 1-4.

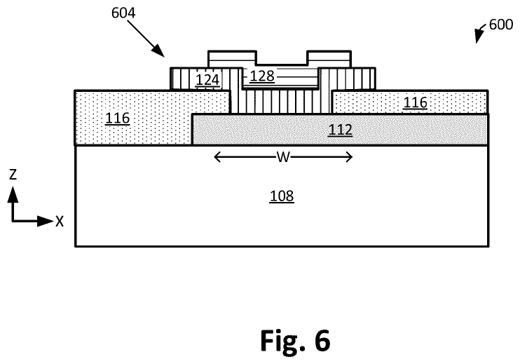

FIG. 6 illustrates a cross-sectional view of an integrated circuit structure 600 comprising a device 108 and an integrated resistive pad 604 on the device 108, wherein the integrated resistive pad 604 comprises a layer 124 having relatively high resistivity (e.g., compared to a resistivity of one or more other layers of the resistive contact pad structure 104) and in contact with a conductive line 112, according to an embodiment of the present disclosure. Thus, the structure 600 of FIG. 6 is at least in part similar to structure 100 of FIG. 1, and similar components of the two structures are labelled using the same labels. However, unlike the structure 100 that included the lower layer 120, the structure 600 doesn't include such a lower layer. Rather, the resistor layer 124 is directly in contact with the conductive line 112. The structure 600 will be apparent, based on the description with respect to the structure 100 of FIG. 1. In an example, the above description with respect to one or more of FIGS. 2-5 may also be applicable to the structure 600 of FIG. 6.

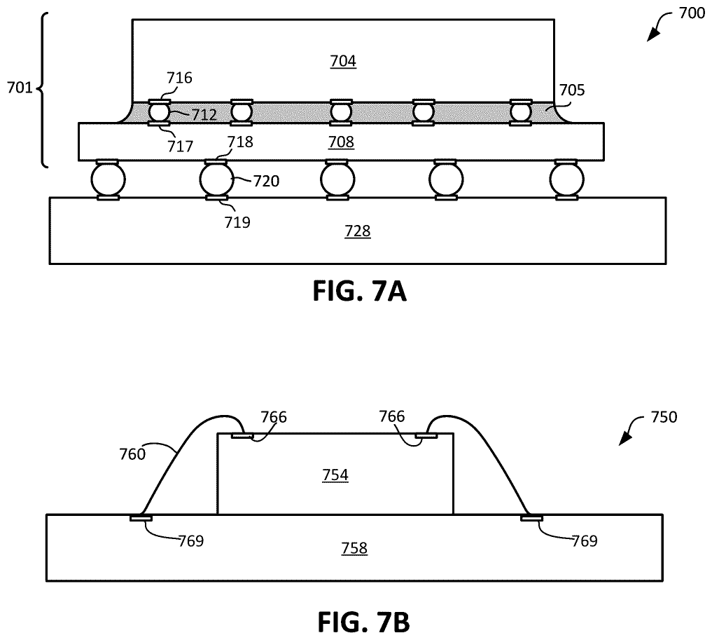

FIG. 7A illustrates a cross-sectional view of an integrated circuit system 700 employing one or more of the resistive contact pad structures described above with respect to FIGS. 1-6, according to an embodiment of the present disclosure. The integrated circuit system 700 comprises a flip-chip integrated circuit package 701, in which an integrated circuit chip or die 704 is arranged in a flip chip configuration (e.g., mounted face-down) on an upper surface of a carrier substrate 708 of the integrated circuit package 701. As illustrated, the die 704 is coupled to the carrier substrate 708 through a plurality of interconnect components 712. In an example, the interconnect components 712 are conductive bumps, such as solder bumps. For example, the solder bumps 712 are arranged in an array or a peripheral bump layout. An underfill material 705 is between the die 704 and the carrier substrate 708.

As illustrated, each interconnect component 712 is coupled to the die 704 through a corresponding contact pad structure 716, and is coupled to the carrier substrate 708 through a corresponding contact pad structure 717. Thus, there are a plurality of contact pad structures 716 coupled to the die 704, and another plurality of contact pad structures 717 coupled to the carrier substrate 708.

In one embodiment, at least some of the contact pad structures 716 are similar to the resistive contact pad structures 104, 104b, and/or 104b described above with respect to FIGS. 1-6, and remaining of the contact pad structures 716 are similar to the non-resistive contact pad structure 220 described above with respect to FIGS. 2-6. Similarly, in one embodiment, at least some of the contact pad structures 717 are similar to the resistive contact pad structures 104, 104b, and/or 104b described above with respect to FIGS. 1-6, and remaining of the contact pad structures 717 are similar to the non-resistive contact pad structures 220 described above with respect to FIGS. 2-6.

As illustrated in FIG. 7A, the carrier substrate 708 is coupled to a PCB 728, through a plurality of interconnect components 720. In an example, the interconnect components 720 are conductive balls, such as solder balls. For example, the carrier substrate 708 is coupled to the PCB 728 through the interconnect components 720, e.g., in a ball grid array (BGA) configuration, and/or another appropriate configuration to couple a carrier substrate to a PCB. In an example, the PCB may be a circuit card assembly (CCA).

As illustrated, each interconnect component 720 is coupled to the carrier substrate 708 through a corresponding contact pad structure 718 on the carrier substrate 708, and is coupled to the PCB 728 through a corresponding contact pad structure 719 on the PCB 728. Thus, there are a plurality of contact pad structures 718 coupled to the carrier substrate 708, and another plurality of contact pad structures 719 coupled to the PCB 728.

In one embodiment, at least some of the contact pad structures 718 are similar to the resistive contact pad structures 104, 104b, and/or 104b described above with respect to FIGS. 1-6, and remaining of the contact pad structures 718 are similar to the non-resistive contact pad structures 220 described above with respect to FIGS. 1-6. Similarly, in one embodiment, at least some of the contact pad structures 719 are similar to the resistive contact pad structures 104, 104b, and/or 104b described above with respect to FIGS. 1-6, and remaining of the contact pad structures 719 are similar to the non-resistive contact pad structures 220 described above with respect to FIGS. 1-6.

Thus, in an example, the device 108 of FIGS. 1-6 may be any of the die 704, the carrier substrate 708, and/or the PCB 728, and the resistive contact pad structures 104, 104a, 104b described above can be any of the contact pad structures 716, 717, 718, and/or 719 of FIG. 7A. Thus, the resistive contact pad structures 104, 104a, 104b described above can be applied (i) at die level (e.g., as one or more of the contact pad structures 716, 717), (ii) at IC package level (e.g., as one or more of the contact pad structures 718), and/or (iii) at the circuit board level (e.g., as one or more of the contact pad structures 719).

FIG. 7B illustrates a cross-sectional view of another integrated circuit system 750 employing one or more of the resistive contact pad structures described above with respect to FIGS. 1-6, according to an embodiment of the present disclosure. The integrated circuit system 750 comprises a wire bonded integrated circuit package, in which an integrated circuit chip or die 754 is arranged in a wire bonded configuration on a carrier substrate 758. As illustrated, the dic 754 is coupled to the carrier substrate 758 through a plurality of conductive wires 760. In an example, each wire 760 is coupled to the die 766 through a corresponding contact pad structure 766, and to the carrier substrate 758 through a corresponding contact pad structure 769. Thus, there are a plurality of contact pad structures 766 coupled to the die 754, and another plurality of contact pad structures 769 coupled to the carrier substrate 758.

In one embodiment, at least some of the contact pad structures 766 are similar to the resistive contact pad structures 104, 104b, and/or 104b described above with respect to FIGS. 1-6, and remaining of the contact pad structures 766 are similar to the non-resistive contact pad structure 220 described above with respect to FIGS. 2-6. Similarly, in one embodiment, at least some of the contact pad structures 769 are similar to the resistive contact pad structures 104, 104b, and/or 104b described above with respect to FIGS. 1-6, and remaining of the contact pad structures 769 are similar to the non-resistive contact pad structures 220 described above with respect to FIGS. 2-6.

FIG. 8 illustrate a flowchart depicting a method 800 of forming the example integrated circuit structures of FIGS. 1-6, in accordance with an embodiment of the present disclosure. FIGS. 9A, 9B, 9C, 9D, 9E, 9F, 9G, 9H, and 9I collectively illustrate an example integrated circuit structure 900 in various stages of processing in accordance with the methodology 800 of FIG. 8, in accordance with an embodiment of the present disclosure. FIGS. 8 and 9A-9I will be discussed in unison.

Referring to FIG. 8, at 804 of the method 800, a device 108 is formed, where the device 108 comprises solder mask 116 on an upper surface of the device 108. The device 108 can be any of the devices of FIG. 7A or 7B, such as any of the dies 704, 754, any of the carrier substrates 708, 758, or the PCB 728. The device 108 can be formed using appropriate techniques to form such a device. Furthermore, also at 804, one or more sections of the top surface of the device 108 is masked using one or more masks 904. The device 108, with the masks 904 thereon, is illustrated in FIG. 9A. The masks 904 can be hard masks, or a shadow mask, or other appropriate type of masks.

The method 800 proceeds from 804 to 808. At 808, sections of the solder mask 116 are removed through openings 905 within the masks 904 (e.g., see FIG. 9B), and layers 120 and 220 are formed through the openings 905 (e.g., see FIG. 9C). The solder mask 116 may be removed using an appropriate etching technique. In an example, the openings 905 are above conductive lines 112 and 212, such that the layers 120 and 220 are formed above, and in contact with, the conductive lines 112, 212, respectively. Example conductive material for the layers 120 and 220 have been described above. In one embodiment, the layers 120, 220 may be formed using an appropriate deposition process (e.g., a conformal deposition process), such as sputtering, chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example.

The method 800 proceeds from 808 to 812. At 812, the masks 904 are removed (e.g., see FIG. 9D), and the layer 220 is masked using one or more masks 908, where the masks 908 form another opening 909 above the layer 120 (e.g., see FIG. 9E). The masks 908 can be hard masks, or a shadow mask, or other appropriate type of masks. In an example, the opening 909 is at least as wide as the layer 120. In the example of FIG. 9E, the opening 909 is wider than the layer 120.

The method 800 proceeds from 812 to 816. At 816, layer 124 is formed through the opening 909 and above the layer 120, wherein the layer 124 is at least as wide as the layer 120, as illustrated in FIG. 9F. In an example and as described above, the layer 124 comprises one or more metals, and/or oxides and/or nitrides thereof. For example, the layer 124 comprises relatively high resistance metal, such as germanium or tellurium. In another example, the layer 124 comprises a metal oxide and/or a metal nitride, such as tantalum oxide, titanium oxide, aluminum oxide, aluminum nitride, and/or other appropriate nitride or oxide. In yet another example, carbide, oxynitride, oxycarbide, or oxycarbonitride of one or more metals may also be used instead.

In an example, the layer 124 is deposited using an appropriate deposition process (e.g., a conformal deposition process), such as sputtering, CVD, PVD, ALD, VPE, MBE, or LPE, for example. In an example where the layer 124 comprises an oxide (such as a metal oxide), a reactive deposition process may be used. For example, during the reactive deposition process, the metal may be deposited in an oxygen-rich chamber or environment, and process parameters (such as temperature and pressure) may be controller such the metal oxide is formed during the deposition process itself. For example, a reactive sputtering process, or a reactive PVD process, or a reactive AVD process, or a reactive CVD process, or another appropriate reactive deposition process can be employed to form the layer 124 comprising a metal oxide. Thus, for the reactive deposition process, not only exposed surfaces of the layer 124 comprises the metal oxide, but the metal oxide is also present in non-exposed sections of the layer 124. In an example, an amount of the metal of the layer 124 that is oxidized may be controlled (e.g., by tuning parameters of the reactive deposition process), to tune a resistance of the layer 124, in an example.

In another example, a regular deposition process (e.g., not a reactive deposition process) may be employed to deposit a metal, and then the metal is oxidized to form metal oxide on exposed surfaces of the metal. Thus, in this case, because only exposed surfaces of the layer 124 is mainly oxidized, the resistance of the layer 124 is relatively less (e.g., compared to the above described scenario where the reactive deposition process is employed).

The method 800 proceeds from 816 to 820. At 820, the masks 908 are removed, and the layer 220 is masked using another mask 912, where the mask 912 forms another opening 913 above the layer 124, as illustrated in FIG. 9G. In an example, the opening 913 can be equal to, or smaller than a width of the layer 124.

The method 800 proceeds from 820 to 824. At 824, the layer 128 is formed through the opening 913 and above the layer 124, as illustrated in FIG. 9H. Subsequently, the masks 912 are removed, as illustrated in FIG. 9I. The layer 128 is deposited using an appropriate deposition process (e.g., a conformal deposition process), such as sputtering, CVD, PVD, ALD, VPE, MBE, or LPE, for example. This completes formation of the resistive contact pad structure 104 comprising the layers 120, 124, and 128, where the resistive contact pad structure 104 is adjacent to the non-resistive contact pad structure 220. Although not illustrated in the method 800, in an example, interconnect components 304 and 344 may be formed above the resistive contact pad structure 104 and the non-resistive contact pad structure 220, e.g., as discussed with respect to FIG. 3.

The method 800 may be appropriate modified to form the structure 400 of FIG. 4. For example, during formation of the structure 400, the layer 324 may be blanket deposited on the layers 120a and 120b (e.g., the masks 908 used to form the layer 124 in the method 800 may be appropriately modified). Accordingly, a continuous and monolithic layer 324 spanning laterally adjacent resistive contact pad structures 104a and 104b of the structure 400 may be formed.

Similarly, the method 800 may be appropriate modified to form the structure 500 of FIG. 5, e.g., by forming two laterally adjacent resistive contact pad structures 104a and 104b, and one laterally adjacent non-resistive contact pad structure 220. Also, the method 800 may be appropriate modified to form the structure 600 of FIG. 6, e.g., by skipping formation of the layer 120 (e.g., the masks 904 may not have an opening to form the layer 120).

Note that the processes in method 800 are shown in a particular order for case of description. However, one or more of the processes may be performed in a different order or may not be performed at all (and thus be optional), in accordance with some embodiments. Numerous variations on method 800 and the techniques described herein will be apparent in light of this disclosure.

### Further Example Embodiments

The following examples pertain to further embodiments, from which numerous permutations and configurations will be apparent.

Example 1. An integrated circuit structure comprising: a first layer comprising a first metal; a second layer above and in contact with the first layer, the second layer comprising a resistive material; a third layer above and in contact with the second layer, the third layer comprising a second metal, wherein the resistive material is different from one or both the first metal and the second metal; and an interconnect component above and in contact with the second layer.

Example 2. The integrated circuit structure of example 1, wherein the interconnect component is a solder bump or a solder ball.

Example 3. The integrated circuit structure of any one of examples 1-2, wherein a resistivity of the resistive material is at least 20% greater than a resistivity of each of the first and third layers.

Example 4. The integrated circuit structure of any one of examples 1-3, wherein the resistive material comprises one or more of (i) a third metal different from the first and second metals, (ii) a metalloid, and (iii) the third metal and at least one of oxygen and nitrogen.

Example 5. The integrated circuit structure of any one of examples 1-4, wherein the first and second metals are the same metal.

Example 6. The integrated circuit structure of any one of examples 1-5, wherein the first layer is in contact with or a part of an integrated circuit die, wherein the interconnect component is between the integrated circuit die and a carrier substrate, and wherein the interconnect component is a solder bump.

Example 7. The integrated circuit structure of any one of examples 1-6, wherein the first layer is in contact with or a part of a carrier substrate, wherein the interconnect component is between the carrier substrate and an integrated circuit die, and wherein the interconnect component is a solder bump.

Example 8. The integrated circuit structure of any one of examples 1-7, wherein the first layer is in contact with or a part of an integrated circuit package, wherein the interconnect component is between the integrated circuit package and a printed circuit board, and wherein the interconnect component is a solder ball.

Example 9. The integrated circuit structure of any one of examples 1-7, wherein the first layer is in contact with or a part of a printed circuit board, wherein the interconnect component is between the printed circuit board and an integrated circuit package, and wherein the interconnect component is a solder ball.

Example 10. The integrated circuit structure of any one of examples 1-9, wherein the interconnect component is a first interconnect component, and wherein the integrated circuit structure further comprises: a fourth layer comprising the first metal, wherein the second layer is above and in contact with the fourth layer, and wherein the second layer extends continuously and monolithically from above the first layer to above the fourth layer; a fifth layer above the second and fourth layers, the fifth layer comprising the second metal; and a second interconnect component above and in contact with the fifth layer.

Example 11. The integrated circuit structure of example 10, wherein the first and second interconnect components are either solder bumps or solder balls.

Example 12. An integrated circuit structure comprising: a device; a resistive contact pad structure on the device, the resistive contact pad structure comprising (i) a lower layer comprising a first metal, (ii) an upper layer above the lower layer, the upper layer comprising a second metal, and (iii) a resistor between the lower layer and the upper layer, wherein a resistivity of the resistor is at least 20% greater than a resistivity of each of the lower and upper layers; and a solder ball or solder bump on the resistive contact pad structure, the solder ball or solder bump configured to couple the device to another device.

Example 13. The integrated circuit structure of example 12, wherein the resistor comprises a third metal, and one or both of oxygen and nitrogen, and wherein the third metal is elementally different from each of the first and second metals.

Example 14. The integrated circuit structure of any one of examples 12-13, wherein the resistive contact pad structure is a first resistive contact pad structure, wherein the lower layer is a first lower layer, wherein the upper layer is a first upper layer, and wherein integrated circuit structure further comprises: a second resistive contact pad structure on the device, the second resistive contact pad structure laterally adjacent to the first resistive contact pad structure, the second resistive contact pad structure comprising (i) a second lower layer comprising the first metal, (ii) a second upper layer above the second lower layer, the second upper layer comprising the second metal, and (iii) the resistor between the second lower layer and the second upper layer; wherein the resistor extends continuously and monolithically from between the first upper and lower layers to between the second upper and lower layers, and wherein the resistor is part of both the first and second resistive contact pad structures.

Example 15. The integrated circuit structure of any one of examples 12-14, further comprising: a non-resistive contact pad structure laterally adjacent to the resistive contact pad structure, the non-resistive contact pad structure comprising a layer comprising the first metal, wherein a bottom surface of the layer of the non-resistive contact pad structure is coplanar with a bottom surface of the lower layer of the resistive contact pad structure, wherein the non-resistive contact pad structure lacks a resistor.

Example 16. The integrated circuit structure of example 15, wherein the solder ball or solder bump is a first solder ball or a solder bump, and wherein the integrated circuit structure further comprises: a second solder ball or solder bump on the layer of the non-resistive contact pad structure; wherein a lower surface of the second solder ball or solder bump is on a first horizontal plane that is lower than a second horizontal plane of a lower surface of the first solder ball or solder bump.

Example 17. The integrated circuit structure of any one of examples 12-16, wherein the device is one of an integrated circuit die, an integrated circuit package, and a printed circuit board (PCB).

Example 18. A method to form a resistive contact pad structure and a non-resistive contact pad structure of an integrated circuit structure, comprising: forming, on a device, a first pad and a laterally adjacent second pad; forming a resistor on the first pad, without forming any resistor on the second pad; forming a third pad on the resistor and above the first pad, wherein a combination of the first pad, the resistor, and the third pad forms a resistive contact pad structure of the device, and wherein the second pad forms a non-resistive contact pad structure of the device.

Example 19. The method of example 18, further comprising: depositing a first interconnect component of the third pad, and a second interconnect component of the second pad, wherein each of the first and second interconnect components is a corresponding solder ball or a solder bump.

Example 20. The method of any one of examples 18-19, further comprising: forming, on the device, a fourth pad that is laterally adjacent to the first and second pads, wherein forming the resistor comprises forming (i) a first section of the resistor on the first pad and (ii) a second section of the resistor on the fourth pad, wherein the first section and the second section of the resistor are part of a monolithic resistor structure; and forming a fifth pad on the second section of the resistor and above the fourth pad, wherein a combination of the fourth pad, the second section of the resistor, and the fifth pad forms another resistive contact pad structure of the device.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future-filed applications claiming priority to this application may claim the disclosed subject matter in a different manner and generally may include any set of one or more limitations as variously disclosed or otherwise demonstrated herein.

What is claimed is:

1. An integrated circuit structure comprising:
a first layer comprising a first metal;
a second layer above and in contact with the first layer, the second layer comprising a resistive material;
a third layer above and in contact with the second layer, the third layer comprising a second metal, wherein the resistive material is different from one or both the first metal and the second metal; and
an interconnect component above and in contact with the second layer.

2. The integrated circuit structure of claim 1, wherein the interconnect component is a solder bump or a solder ball.

3. The integrated circuit structure of claim 1, wherein a resistivity of the resistive material is at least 20% greater than a resistivity of each of the first and third layers.

4. The integrated circuit structure of claim 1, wherein the resistive material comprises one or more of (i) a third metal different from the first and second metals, (ii) a metalloid, and (iii) the third metal and at least one of oxygen and nitrogen.

5. The integrated circuit structure of claim 1, wherein the first and second metals are the same metal.

6. The integrated circuit structure of claim 1, wherein the first layer is in contact with or a part of an integrated circuit die, wherein the interconnect component is between the integrated circuit die and a carrier substrate, and wherein the interconnect component is a solder bump.

7. The integrated circuit structure of claim 1, wherein the first layer is in contact with or a part of a carrier substrate, wherein the interconnect component is between the carrier substrate and an integrated circuit die, and wherein the interconnect component is a solder bump.

8. The integrated circuit structure of claim 1, wherein the first layer is in contact with or a part of an integrated circuit package, wherein the interconnect component is between the integrated circuit package and a printed circuit board, and wherein the interconnect component is a solder ball.

9. The integrated circuit structure of claim 1, wherein the first layer is in contact with or a part of a printed circuit board, wherein the interconnect component is between the printed circuit board and an integrated circuit package, and wherein the interconnect component is a solder ball.

10. The integrated circuit structure of claim 1, wherein the interconnect component is a first interconnect component, and wherein the integrated circuit structure further comprises:
a fourth layer comprising the first metal, wherein the second layer is above and in contact with the fourth layer, and wherein the second layer extends continuously and monolithically from above the first layer to above the fourth layer;
a fifth layer above the second and fourth layers, the fifth layer comprising the second metal; and
a second interconnect component above and in contact with the fifth layer.

11. The integrated circuit structure of claim 10, wherein the first and second interconnect components are either solder bumps or solder balls.

12. An integrated circuit structure comprising:
a device;
a resistive contact pad structure on the device, the resistive contact pad structure comprising (i) a lower layer comprising a first metal, (ii) an upper layer above the lower layer, the upper layer comprising a second metal, and (iii) a resistor between the lower layer and the upper layer, wherein a resistivity of the resistor is at least 20% greater than a resistivity of each of the lower and upper layers; and
a solder ball or solder bump on the resistive contact pad structure, the solder ball or solder bump configured to couple the device to another device.

13. The integrated circuit structure of claim 12, wherein the resistor comprises a third metal, and one or both of oxygen and nitrogen, and wherein the third metal is elementally different from each of the first and second metals.

14. The integrated circuit structure of claim 12, wherein the resistive contact pad structure is a first resistive contact pad structure, wherein the lower layer is a first lower layer, wherein the upper layer is a first upper layer, and wherein integrated circuit structure further comprises:
a second resistive contact pad structure on the device, the second resistive contact pad structure laterally adjacent to the first resistive contact pad structure, the second resistive contact pad structure comprising (i) a second lower layer comprising the first metal, (ii) a second upper layer above the second lower layer, the second upper layer comprising the second metal, and (iii) the resistor between the second lower layer and the second upper layer;
wherein the resistor extends continuously and monolithically from between the first upper and lower layers to between the second upper and lower layers, and wherein the resistor is part of both the first and second resistive contact pad structures.

15. The integrated circuit structure of claim 12, further comprising:
a non-resistive contact pad structure laterally adjacent to the resistive contact pad structure, the non-resistive contact pad structure comprising a layer comprising the first metal, wherein a bottom surface of the layer of the non-resistive contact pad structure is coplanar with a bottom surface of the lower layer of the resistive contact pad structure, wherein the non-resistive contact pad structure lacks a resistor.

16. The integrated circuit structure of claim 15, wherein the solder ball or solder bump is a first solder ball or a solder bump, and wherein the integrated circuit structure further comprises:
a second solder ball or solder bump on the layer of the non-resistive contact pad structure;
wherein a lower surface of the second solder ball or solder bump is on a first horizontal plane that is lower than a second horizontal plane of a lower surface of the first solder ball or solder bump.

17. The integrated circuit structure of claim 12, wherein the device is one of an integrated circuit die, an integrated circuit package, and a printed circuit board (PCB).

18. A method to form a resistive contact pad structure and a non-resistive contact pad structure of an integrated circuit structure, comprising:
forming, on a device, a first pad and a laterally adjacent second pad;
forming a resistor on the first pad, without forming any resistor on the second pad;
forming a third pad on the resistor and above the first pad, wherein a combination of the first pad, the resistor, and the third pad forms a resistive contact pad structure of the device, and wherein the second pad forms a non-resistive contact pad structure of the device.

19. The method of claim 18, further comprising:
depositing a first interconnect component of the third pad, and a second interconnect component of the second pad, wherein each of the first and second interconnect components is a corresponding solder ball or a solder bump.

20. The method of claim 18, further comprising:
forming, on the device, a fourth pad that is laterally adjacent to the first and second pads, wherein forming the resistor comprises forming (i) a first section of the resistor on the first pad and (ii) a second section of the resistor on the fourth pad, wherein the first section and the second section of the resistor are part of a monolithic resistor structure; and
forming a fifth pad on the second section of the resistor and above the fourth pad, wherein a combination of the fourth pad, the second section of the resistor, and the fifth pad forms another resistive contact pad structure of the device.
